(19) United States
(12) Patent Application Publication
(10) Pub. No.: US 2026/0341331 A1
(43) Pub. Date: Oct. 29, 2026

(54) Efficient Refreshing of Spare Rows

(71) Applicant: Micron Technology, Inc., Boise, ID (US)

(72) Inventors: Yang Lu, Boise, ID (US); John E. Riley, McKinney, TX (US)

(73) Assignee: Micron Technology, Inc., Boise, ID (US)

(21) Appl. No.: 19/188,755

(22) Filed: Apr. 24, 2025

(51) Int. Cl. G11C 11/406; G11C 29/44

(52) U.S. Cl. CPC G11C 11/40618; G11C 29/4401

(57) ABSTRACT

Apparatuses and techniques are described for efficiently refreshing spare rows that can be used to repair rows of a “main” memory array. In example aspects, a memory device conserves power and timing resources by refreshing spare rows that are in an active state (e.g., spare rows that are used to repair rows within a memory array of the memory device) and skipping the refreshing of spare rows that are in an inactive state. At least one spare row that is in the inactive state is available for use in a future repair operation. The power and/or timing resources that are conserved through efficient refreshing of the spare rows of a reserve memory array can optionally be used to perform other operations, such as an error-correction-code operation, a refresh operation for mitigating usage-based-disturbance within the memory device, and/or a refresh operation on an active spare row within the reserve memory array.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for efficient refreshing of spare rows are described with reference to the following drawings. The same numbers are used throughout the drawings to reference like features and components:

FIG. 1 illustrates example apparatuses that can implement aspects of efficient refreshing of spare rows;

FIG. 2 illustrates an example computing system that can implement aspects of efficient refreshing of spare rows;

FIG. 3 illustrates an example memory device capable of performing efficient refreshing of spare rows;

FIG. 4 illustrates example states of spare rows that form at least a portion of a reserve memory array;

FIG. 5 illustrates an example flow diagram for performing efficient refreshing of spare rows;

FIG. 6 illustrates example inputs and an example output of a spare-row state-identifier circuit for performing aspects of efficient refreshing of spare rows;

FIG. 7 illustrates a first example implementation of a spare-row state-indicator circuit for performing aspects of efficient refreshing of spare rows;

FIG. 8 illustrates a second example implementation of a spare-row state-indicator circuit for performing aspects of efficient refreshing of spare rows; and

FIG. 9 illustrates an example method for performing efficient refreshing of spare rows.

### DETAILED DESCRIPTION

### Overview

Computing devices provide various services for users of mobile devices and server devices. Some computing devices include a host device, which may include a memory controller, and a memory device for storing information. For some applications, such as portable electronic devices that operate on battery power and data centers that employ thousands of memory devices, reducing power usage by memory devices can provide appreciable improvements in energy efficiency.

For example, double data rate synchronous dynamic random-access memory (DDR SDRAM), including low-power DDR (LPDDR) SDRAM, is a volatile memory. Volatile memory loses stored information if the power to the memory is not maintained. The memory cells of DRAM devices are typically made using pairs of capacitors and transistors. Information is stored using charge levels that are applied to the capacitors. This charge, however, gradually leaks from the memory cells, so the data will eventually be lost if the capacitor is not recharged. Consequently, to maintain an appropriate charge that reflects the stored data, the memory cells are periodically refreshed by restoring the correct charge level.

The rate of charge leakage from each capacitor is generally known or can be predicted. Based on this rate, the charge of each capacitor in the memory device can be repeatedly refreshed (e.g., periodically refreshed) sufficiently frequently to counteract this rate of charge loss at the capacitors. Generally, each memory cell in a volatile memory is refreshed within a DRAM retention time (e.g., approximately 64 milliseconds (ms)) to maintain the integrity of stored data. To perform a refresh operation, logic of the memory reads data from a memory cell corresponding to a refresh address into a temporary storage buffer (e.g., a sense amp) and writes the data back to the memory cell with the proper “full” charge. A refresh address can include a memory cell address, a row address, a bank address, and the like.

The memory device can include a memory array (e.g., a “main” memory array) and a reserve memory array. Defective or faulty memory elements (e.g., rows and/or columns) within the main memory array can be effectively “repaired” or “replaced” using memory elements (e.g., spare rows and/or spare columns) of the reserve memory array. During operation, the memory device is to refresh rows within the memory array as well as spare rows within the reserve memory array. Since a spare row can be used to repair various rows within the memory array, some memory devices separately refresh rows within the main memory array and spare rows within the reserve memory array. In other words, a refresh pump (e.g., a time interval for performing a refresh operation) can be assigned to refreshing a row within the memory array or can be assigned to refreshing a spare row within the reserve memory array. Consequently, these memory devices can reserve at least part of some refresh pumps for refreshing the reserve memory array.

Some of the spare rows within the reserve memory array are available for use in future repair operations, but they have yet to be used for such repairs. These spare rows can be referred to as unused spare rows. While a spare row is unused, it does not store meaningful data. Refreshing these unused spare rows can therefore waste power and timing resources.

To address this problem, this document describes techniques for efficiently refreshing spare rows of a reserve memory array. In example aspects, a memory device conserves power and timing resources by refreshing spare rows that are in an active state (e.g., spare rows that are used to repair rows within a memory array of the memory device) and skipping the refreshing of spare rows that are in an inactive state. At least one spare row that is in the inactive state is available for use in a future repair operation. The power and/or timing resources that are conserved through efficient refreshing of the spare rows can optionally be used to perform other operations, such as an error-correction-code operation, a refresh operation for mitigating usage-based-disturbance within the memory device, and/or a refresh operation on an active spare row within the reserve memory array.

### Example Operating Environments

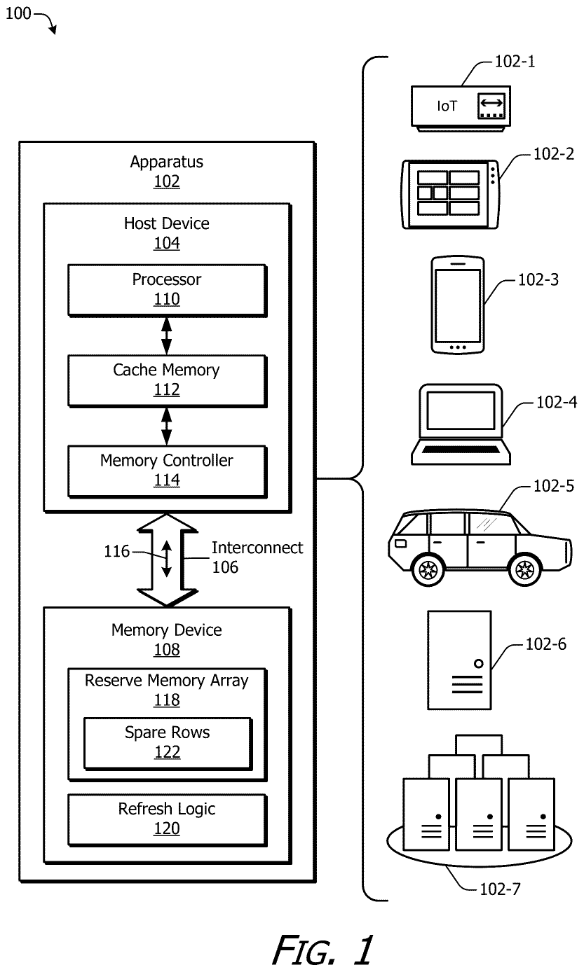

FIG. 1 illustrates, at 100 generally, an example operating environment including an apparatus 102 that can perform efficient refreshing of spare rows. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one reserve memory array 118 and at least one instance of refresh logic 120. The reserve memory array 118 includes one or more spare rows 122. Although not explicitly shown, the reserve memory array 118 can also include one or more spare columns. The reserve memory array 118 can alternatively be referred to as a redundant memory array, a backup memory array, or a spare memory array. Generally speaking, the reserve memory array 118 includes memory that is not available (or addressable) for use by default, but can be called into use as a replacement for a portion of a main memory array that experiences a failure or fault, or is otherwise considered defective. The spare rows 122 and/or spare columns within the reserve memory array 118 can be used in a repair operation to functionally replace normal rows and/or columns within the memory array that are considered faulty.

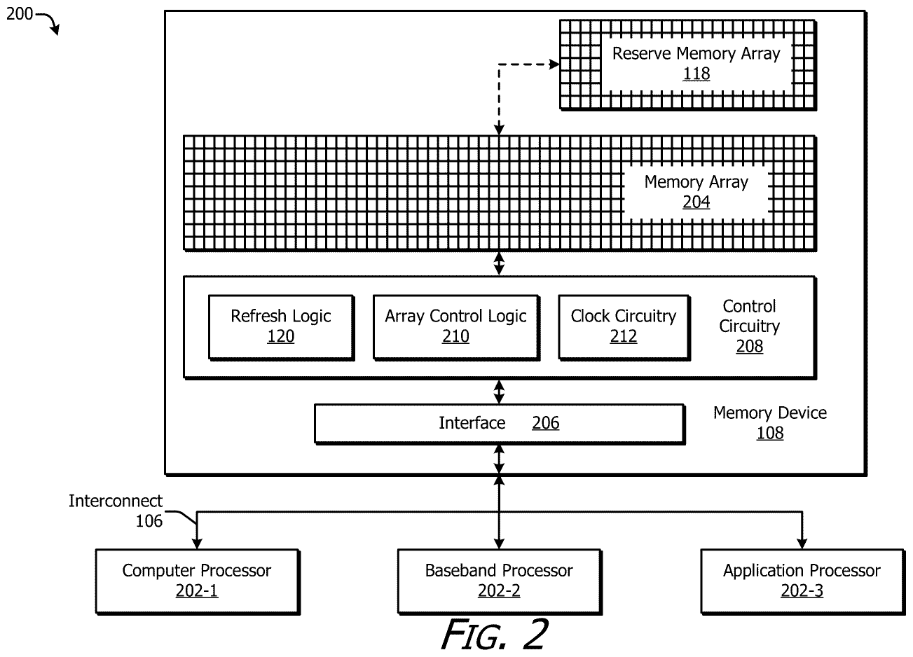

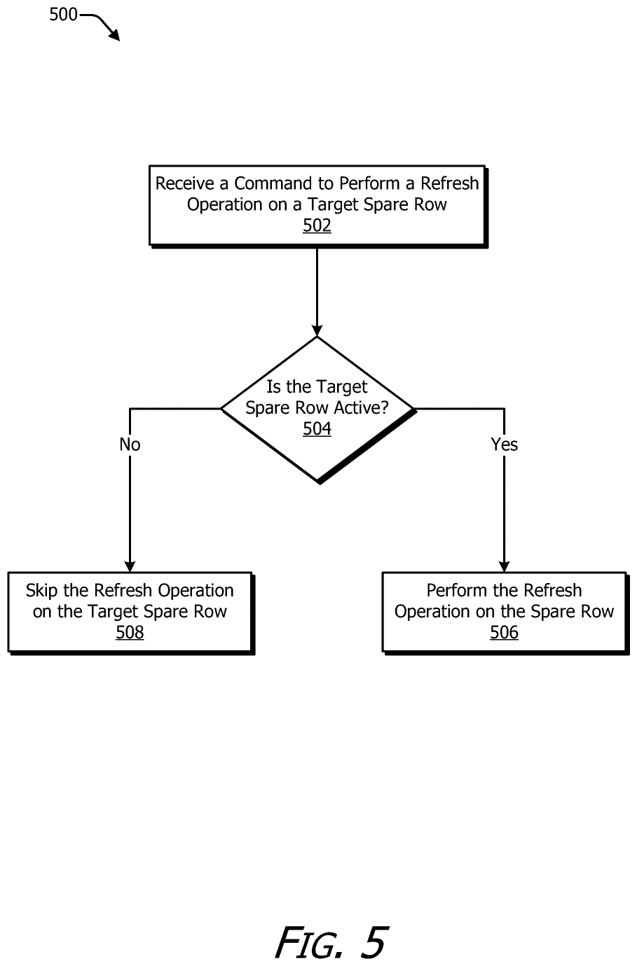

The refresh logic 120 can perform one or more refresh operations on the reserve memory array 118. A refresh operation can involve reading data from a targeted spare row 122 into a temporary storage buffer (e.g., a sense amp) and writing the data back to the spare row 122 with the proper “full” charge. Example refresh operations can be associated with a self-refresh mode or an auto-refresh mode. The refresh logic 120 can perform efficient refreshing of the spare rows 122 by skipping the refreshing of spare rows 122 that are unused and/or disabled, as further described with respect to FIG. 5. Other components of the memory device 108 are further described with respect to FIG. 2.

FIG. 2 illustrates an example computing system 200 that can perform serialized update procedures during a refresh period. In some implementations, the computing system 200 includes at least one memory device 108, at least one interconnect 106, and at least one processor 202. The memory device 108 can include, or be associated with, at least one reserve memory array 118, at least one memory array 204, at least one interface 206, and the control circuitry 208 (or periphery circuitry). The control circuitry 208 and the reserve memory array 118 are operatively coupled to the memory array 204.

The memory array 204 includes an array of memory cells, including but not limited to memory cells of DRAM, SDRAM, three-dimensional (3D) stacked DRAM, DDR memory, LPDDR SDRAM, and so forth. In general, the memory array 204 can alternatively be referred to as a main memory array, a functional memory array, or a normal memory array of the memory device 108.

The reserve memory array 118 and the memory array 204 are structurally distinct from each other. In some implementations, the spare rows 122 within the reserve memory array 118 are parallel to and immediately adjacent to the rows within the memory array 204. Likewise, the spare columns within the reserve memory array 118 can be parallel to and immediately adjacent to the columns within the memory array 204.

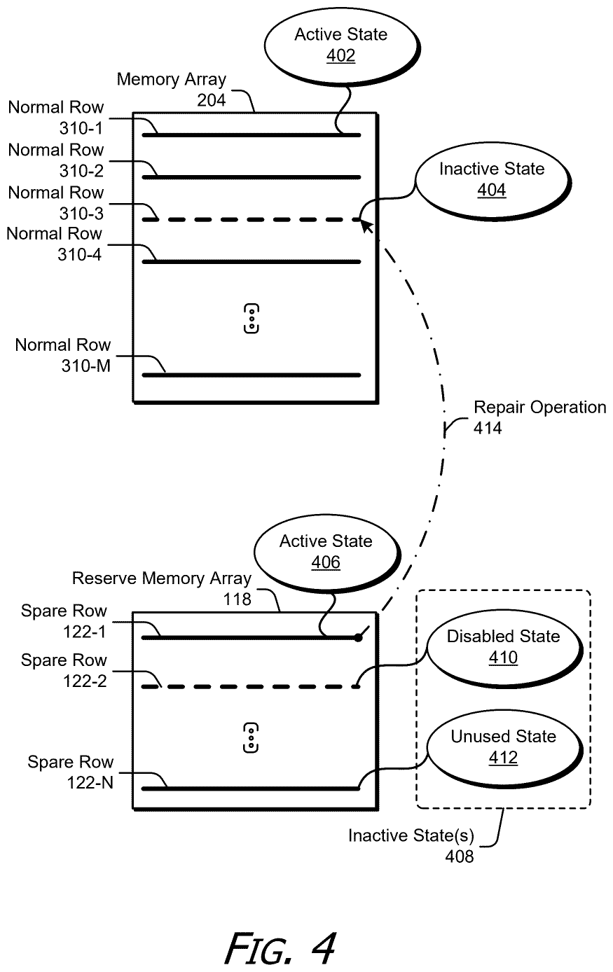

Generally speaking, the rows and columns of the memory array 204 are active (e.g., enabled or “live”) by default while the spare rows 122 and/or the spare columns within the reserve memory array 118 are in an inactive state (e.g., an unused state) by default. Over time, the memory device 108 can perform one or more repair operations to address faulty memory elements within the memory array 204. An example repair operation can cause a row within the memory array 204 to be effectively swapped or replaced with one of the unused spare rows 122 within the reserve memory array 118, as represented by the dashed line between the reserve memory array 118 and the memory array 204 in FIG. 2. The reserve memory array 118 and the memory array 204 are further described with respect to FIG. 4.

The reserve memory array 118, the memory array 204, and the control circuitry 208 may be components on a single semiconductor die or on separate semiconductor dies. The reserve memory array 118, the memory array 204, or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the refresh logic 120, at least one array control circuit 210, and at least one instance of clock circuitry 212.

The refresh logic 120 includes circuitry for performing refresh operations, such as a self-refresh operation or an auto-refresh operation. The array control circuit 210 includes circuitry that provides command decoding, address decoding, input/output functions, amplification circuitry, power supply management, power control modes, and other functions. The clock circuitry 212 synchronizes various memory components with one or more external clock signals provided over the interconnect 106, including a command-and-address clock or a data clock. The clock circuitry 212 can also use an internal clock signal to synchronize memory components and may provide timer functionality.

The interface 206 can couple the control circuitry 208, the memory array 204, or the reserve memory array 118 directly or indirectly to the interconnect 106. In some implementations, the refresh logic 120, the array control circuit 210, and the clock circuitry 212 can be part of a single component (e.g., the control circuitry 208). In other implementations, one or more of the refresh logic 120, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi™, Bluetooth™, near field, or another technology or protocol for wireless communication.

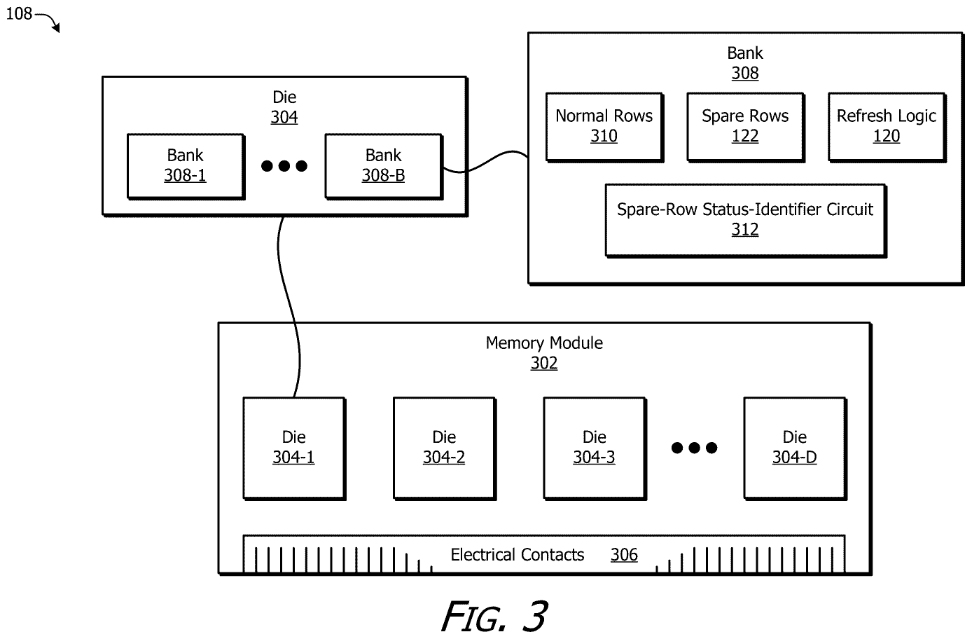

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). An example implementation of the memory device 108 is further described with respect to FIG. 3.

FIG. 3 illustrates an example memory device 108 in which aspects of efficient refreshing of spare rows 122 can be implemented. The memory device 108 includes a memory module 302, which can include multiple dies 304. As illustrated, the memory module 302 includes a first die 304-1, a second die 304-2, a third die 304-3, and a D^{th} die 304-D, with D representing a positive integer. The memory module 302 can be a SIMM or a DIMM. As another example, the memory module 302 can interface with other components via a bus interconnect (e.g., a Peripheral Component Interconnect Express (PCIe®) bus). The memory device 108 illustrated in FIGS. 1 and 2 can correspond, for example, to multiple dies (or dice) 304-1 through 304-D, or a memory module 302 with two or more dies 304. As shown, the memory module 302 can include one or more electrical contacts 306 (e.g., pins) to interface the memory module 302 to other components.

The memory module 302 can be implemented in various manners. For example, the memory module 302 may include a printed circuit board, and the multiple dies 304-1 through 304-D may be mounted or otherwise attached to the printed circuit board. The dies 304 (e.g., memory dies) may be arranged in a line or along two or more dimensions (e.g., forming a grid or array). The dies 304 may have a similar size or may have different sizes. Each die 304 may be similar to another die 304 or different in size, shape, data capacity, or control circuitries. The dies 304 may also be positioned on a single side or on multiple sides of the memory module 302.

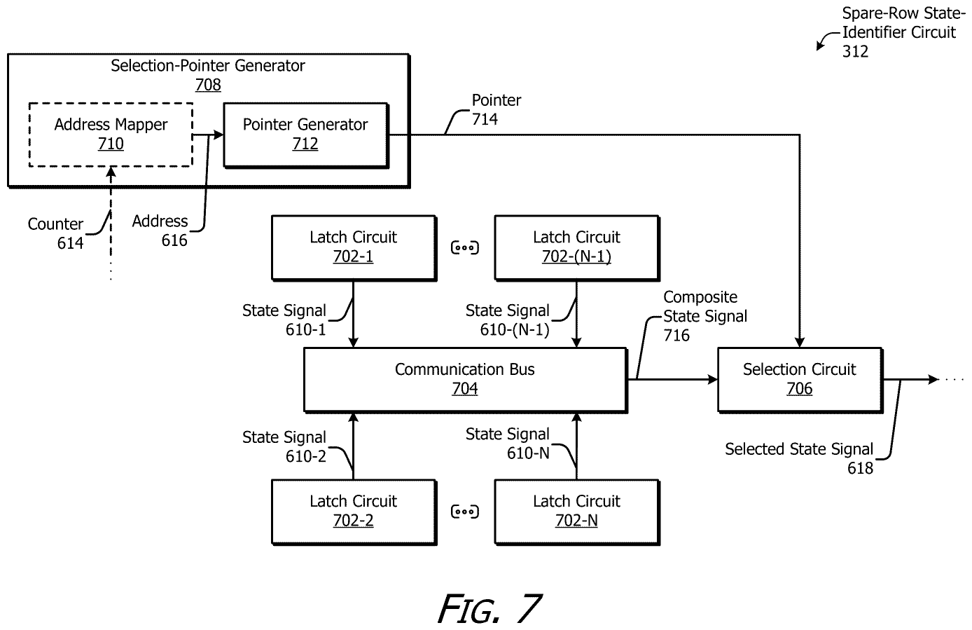

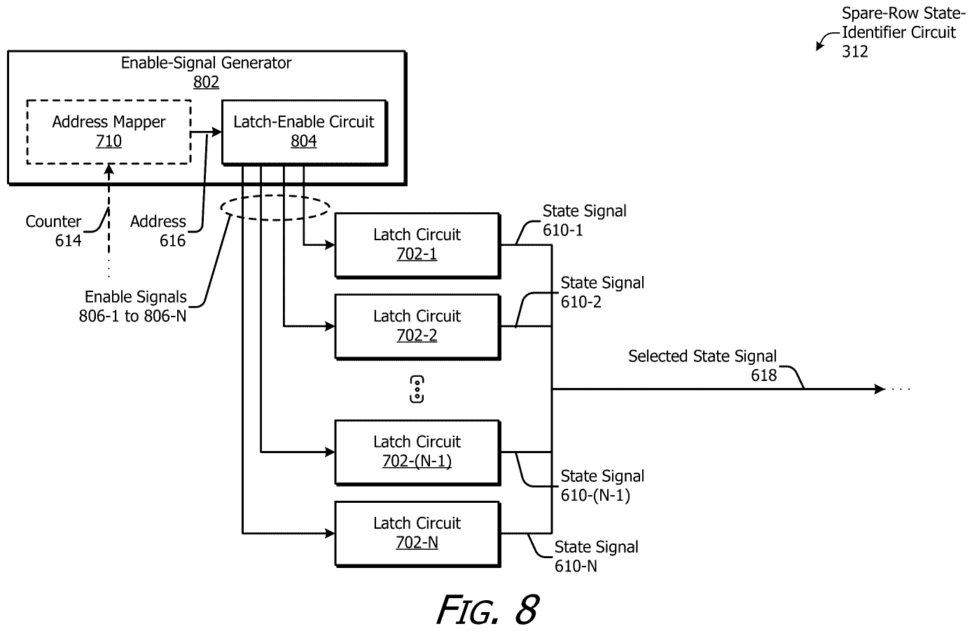

Each one of the dies 304-1 to 304-D can include one or more banks 308-1 to 308-B, where B represents a positive integer. The banks 308-1 to 308-B can be associated with one or more bank groups. Each bank 308 includes multiple normal rows 310, which form at least a portion of the memory array 204. Each bank 308 also includes or has access to one or more spare rows 122, which form at least a portion of the reserve memory array 118. Additionally, each bank 308 is associated with corresponding refresh logic 120 and a spare-row state-identifier circuit 312. Although the spare-row state-identifier circuit 312 is shown to be distinct from the refresh logic 120 in FIG. 3, other implementations are also possible in which the spare-row state-identifier circuit 312 is considered part of the refresh logic 120. The spare-row state-identifier circuit 312 can pass information about a status of a target spare row 122 to the refresh logic 120. The spare-row state-identifier circuit 312 can be implemented at the local-bank level. This means that each bank 308 within the die 304 can have a corresponding spare-row state-identifier circuit 312. Example implementations of the spare-row state-identifier circuit 312 are further described with respect to FIGS. 7 and 8.

### Example Techniques and Hardware

FIG. 4 illustrates example states of normal rows 310 of the memory array 204 and example states of spare rows 122 of the reserve memory array 118. In this example, the memory array 204 is shown to include normal rows 310-1, 310-2, 310-3, 310-4 . . . 310-M. The reserve memory array 118 includes spare rows 122-1, 122-2 . . . 122-N. The variables N and M represent positive integers. In example implementations, the variable M has a value that is greater than a value of the variable N.

The normal rows 310 within the memory array 204 can selectively be in an active state 402 or an inactive state 404. The active state 402 indicates that the normal row 310 can be used to store data. While in the active state 402, the normal row 310 can support normal memory operations, such as normal read and/or write operations. In contrast, the inactive state 404 indicates that the normal row 310 cannot be used to store data. Normal rows 310 that are in the inactive state 404 can be previously determined by the memory device 108 to be faulty and/or defective in some manner. In some implementations, the refresh logic 120 is designed to refresh normal rows 310 that are in the active state 402 and skip the refreshing of normal rows 310 that are in the inactive state 404.

The spare rows 122 within the reserve memory array 118 can similarly be in an active state 406 or an inactive state 408. The active state 406 indicates that the spare row 122 is used to repair a normal row 310 within the memory array 204. The active state 406 can also be referred to as a used state. In contrast, the inactive state 408 indicates that the spare row 122 is not used to repair a normal row 310.

There are different types of inactive states 408. A first inactive state 408 includes a disabled state 410, which indicates that the spare row 122 is faulty or defective in some manner. In this case, the memory device 108 disables the spare row 122 so that it is not used to repair a normal row 310. In other words, the disabled state 410 disqualifies the spare row 122 to be used in a future repair operation. A second inactive state 408 includes an unused state 412. The unused state 412 indicates that the spare row 122 can be used in a future repair operation 414 but is currently not in use.

In this example, the memory device 108 determines that the normal row 310-3 is faulty or defective, as indicated by the dashed line. For example, the memory device 108 can determine that the normal row 310-3 is faulty based on a built-in self-test (BIST). To address the faulty normal row 310-3, the memory device 108 performs a repair operation 414, which causes the spare row 122-1 to effectively replace the normal row 310-3. In this case, the spare row 122-1 stores the data that the normal row 310-3 would otherwise store. After the repair operation 414 is performed, the normal row 310-3 can be considered to be in a repaired state.

The memory device 108 can also determine that the spare row 122-2 is faulty, as indicated by the dashed line. In this situation, the spare row 122-2 is placed in the disabled state 410 and the memory device 108 will not perform a future repair operation 414 using the spare row 122-2. The spare row 122-N is in the unused state 412. This means that the spare row 122-N can be used in a future repair operation 414 to repair one of the normal rows 310. The state of the spare row 122-N can change over time. For example, after the spare row 122-N is used in a repair operation, the state of the spare row 122-N changes from the inactive state 408 (e.g., the unused state 412) to the active state 406. To conserve power and/or timing resources, the refresh logic 120 can skip the refreshing of spare rows 122 that are in the inactive state 408, including one or more spare rows 122 that are in the unused state 412 and/or one or more spare rows 122 that are in the disabled state 410, as further described with respect to FIG. 5.

FIG. 5 illustrates an example flow diagram 500 for performing efficient refreshing of spare rows 122. At 502, the refresh logic 120 receives a command to perform a refresh operation on a target spare row 122. Explained another way, the command causes the refresh logic 120 to assign (e.g., to dedicate) a refresh pump for performing a refresh operation on the target spare row 122 of the reserve memory array 118. The command can be associated with a self-refresh mode or an auto-refresh mode.

Refresh operations can be controlled in at least two ways. First, refresh operations can be initiated, controlled, or timed by the host device 104 that is located external to the memory device 108. For instance, the memory controller 114 can issue an auto-refresh command to the memory device 108. Second, refresh operations can be initiated, controlled, timed or otherwise performed internal to the memory device 108 using a self-refresh operation. In an auto-refresh mode, the memory controller 114 may issue a refresh command (e.g., an auto-refresh command) that corresponds to or includes one all-bank refresh (ABR) command or multiple per-bank refresh (PBR) commands, the quantity of which depends on the bank configuration. The memory controller 114 can issue the refresh command at a frequency (e.g., at an average refresh interval (tREFI)) that is sufficient to refresh each memory cell within the DRAM retention time.

At 504, the refresh logic 120 determines if the target spare row 122 is in the active state 406. If the spare row 122 is in the active state 406, the process continues at 506. At 506, the memory device 108 performs the refresh operation on the target spare row 122. This means that the memory device 108 activates the target spare row 122 based on the command that is received at 502.

Alternatively, if the spare row 122 is in the inactive state 408 (e.g., one of the inactive states 408), the process continues at 508. At 508, the refresh logic 120 skips (e.g., does not perform) the refresh operation on the target spare row 122. This means that the memory device 108 does not activate the target spare row 122 based on the command received at 502, even though the command may have had a pump that was initially assigned to the target spare row 122. By skipping the refresh operation, the memory device 108 avoids refreshing spare rows 122 that do not store meaningful data (e.g., spare rows 122 that are in the disabled state 410 or the unused state 412). In this way, the memory device 108 can conserve power and/or timing resources.

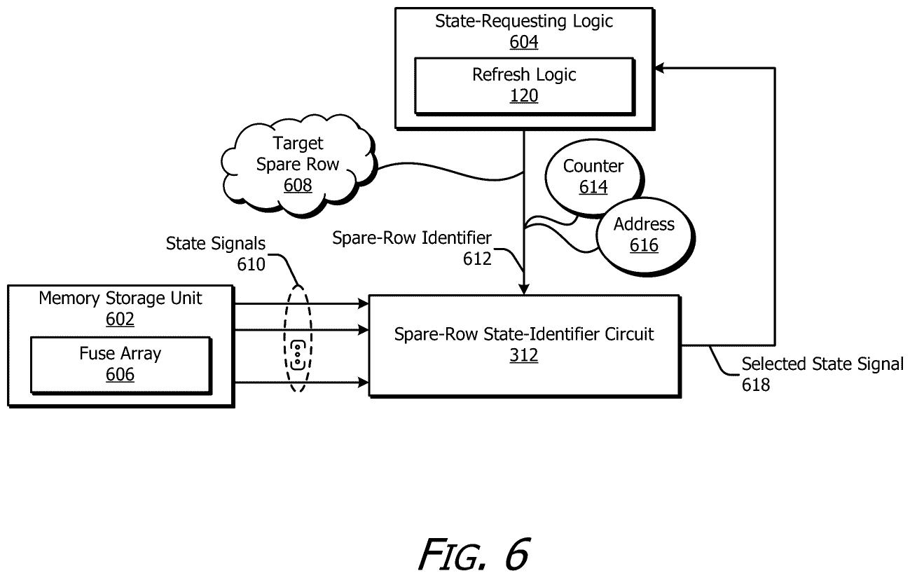

The memory device 108 can optionally perform other operations based on the skipping of the refresh operation. For example, the memory device 108 can perform an error-correction-code operation on a normal row 310 of the memory array 204, refresh a normal row 310 of the memory array 204 to mitigate usage-based disturbance (e.g., refresh a victim row), or refresh a different spare row 122 of the reserve memory array 118 if this spare row 122 is in the active state 406. To perform effective refreshing of the spare rows 122, the refresh logic 120 uses the spare-row state-identifier circuit 312 to provide a state of the target spare row 122, as further described with respect to FIG. 6.

FIG. 6 illustrates example inputs and an example output of the spare-row state-identifier circuit 312. In the depicted configuration, the spare-row state-identifier circuit 312 is coupled to a memory storage unit 602 and state-requesting logic 604. The memory storage unit 602 can be realized as at least one fuse array 606, at least one register, and so forth. The state-requesting logic 604 generally represents any type of logic or circuit that requests information about a state of regarding a target spare row 608. As an example, the state-requesting logic 604 can include at least a portion of the refresh logic 120. In this case, the target spare row 608 represents a spare row 608 that is associated with a commanded refresh operation (e.g., associated with a scheduled refresh pump). Other examples are also possible in which the state-requesting logic 604 can include another circuit or logic associated with the control circuitry 208, such as repair logic.

During operation, the memory storage unit 602 stores state signals 610. The state signals 610 contain information regarding the states of the spare rows 122, respectively. This information can indicate if the spare row 122 is being used to repair a normal row 310 or can indicate if the spare row 122 is not being used to repair a normal row 310. In some implementations, each state signal 610 can indicate that the corresponding spare row 122 is in one of two states, such as the active state 406 or the inactive state 408. In other implementations, each state signal 610 can indicate that the corresponding spare row 122 is in one of three states, such as the active state, the disabled state 410, or the unused state 412.

Consider the example of FIG. 4 in which the spare row 122-1 is in the active state 406 and the spare rows 122-2 and 122-N are in the inactive state 408 (e.g., one of the inactive states 408 of FIG. 4). In this case, the fuse array 606 can have a blown fuse that indicates the spare row 122-1 is in the active state 406. The fuse array 606 can also have fuses that are not blown to indicate that the spare rows 122-2 and 122-N are in the inactive state 408.

The state-requesting logic 604 (e.g., the refresh logic 120) passes a spare-row identifier 612 to the spare-row state-identifier circuit 312. The spare-row identifier 612 indicates the target spare row 608 (e.g., the spare row 608 for which the state-requesting logic 604 is requesting state information). In example implementations, the spare-row identifier 612 can include a counter 614, such as a refresh counter, whose value can be used to identify the target spare row 608. In other implementations, the spare-row identifier 612 can include an address 616 (e.g., a refresh address) of the target spare row 608.

The spare-row state-identifier circuit 312 generates a selected state signal 618 based on the state signals 610 and the spare-row identifier 612. In more detail, the spare-row state-identifier circuit 312 uses the spare-row identifier 612 to select one of the state signals 610 that correspond to the target spare row 608. The spare-row state-identifier circuit 312 can then pass the state signal 610 that is selected as the selected state signal 618. Other implementations are also possible in which the spare-row state-identifier circuit 312 uses the spare-row identifier 612 to extract information from a state signal 610 that corresponds to the target spare row 608. In this case, the spare-row state-identifier circuit 312 can generate the selected state signal 618 to include the extracted information, which specifies a state of the target spare row 608. The spare-row state-identifier circuit 312 passes the selected state signal 618 to the state-requesting logic 604. In general, the selected state signal 618 indicates a state of the target spare row 608.

The state-requesting logic 504 receives the selected state signal 618 and takes appropriate action based on the selected state signal 618. For example, the refresh logic 120 can perform a refresh operation on the target spare row 122 based on the selected state signal 618 indicating that the target spare row 608 is in the active state 406, as described at 506 in FIG. 5. Alternatively, the refresh logic 120 can skip the refresh operation on the target spare row 608 based on the selected state signal 618 indicating that the target spare row 608 is in the inactive state 408 (e.g., the disabled state 410 or the unused state 412). By not refreshing spare rows 122 that are inactive, the memory device 108 can conserve power and/or timing resources to efficiently refresh the spare rows 122.

Generally speaking, an operation of the spare-row state-identifier circuit 312 can be sufficiently fast so as to not significantly impact a timing of the refresh operation. To further reduce the impact of the spare-row state-identifier circuit 312 on refresh timing, the spare-row state-identifier circuit 312 can generate, in advance, a next selected state signal 618 associated with a next spare-row identifier 612. This operation can be performed in advance because an order in which refresh operations are assigned to the spare rows 122 can be predictable or follow a known pattern. In this way, the refresh logic 120 can determine whether to perform or skip a next refresh operation on the spare rows 122 prior to receiving a command to perform the next refresh operation. Example implementations of the spare-row state-identifier circuit 312 are further described with respect to FIGS. 7 and 8.

FIG. 7 illustrates a first example implementation of the spare-row state-identifier circuit 312 for performing aspects of efficient refreshing of spare rows 122. In the depicted configuration, the spare-row state-identifier circuit 312 includes multiple latch circuits 702, at least one communication bus 704 (e.g., at least one bus), and at least one selection circuit 706. The multiple latch circuits 702 include latch circuits 702-1, 702-2 . . . 702-(N-1) and 702-N. The multiple latch circuits 702 are respectively associated with the multiple spare rows 122 of the reserve memory array 118. For example, the latch circuit 702-1 corresponds with the spare row 122-1, and the latch circuit 702-N corresponds with the spare row 122-N. The latch circuits 702 are coupled between the memory storage unit 602 (not shown) and the communication bus 704. The selection circuit 706 is coupled between the communication bus 704 and the state-requesting logic 604 (e.g., the refresh logic 120) (not shown). The selection circuit 706 can perform a similar function as a multiplexer or a switching circuit. In general, the selection circuit 706 enables information provided by a selected one of the latch circuits 702 to be outputted as part of the selected state signal 618.

The spare-row state-identifier circuit 312 also includes at least one selection-pointer generator 708. In various implementations, the selection-pointer generator 708 optionally includes at least one address mapper 710 and includes at least one pointer generator 712. In this example, the selection-pointer generator 708 includes the address mapper 710 to enable the counter 614 to be provided as the spare-row identifier 612. In an alternative implementation that provides the address 616 as the spare-row identifier 612, the selection-pointer generator 708 can be implemented without the address mapper 710. In this example, the pointer generator 712 is coupled between the address mapper 710 and the selection circuit 706.

During operation, the latch circuits 702 store the state signals 610 provided by the memory storage unit 602. In particular, the latch circuits 702 read the state signals 610 from the memory storage unit 602 and latch the state signals 610. In some implementations, the latch circuits 702 include enable judgement logic that can generate the state signal 610 with binary information that indicates if the corresponding spare row 122 is in the active state 406 or the inactive state 408 (e.g., the disabled state 410 or the unused state 412).

The latch circuits 702 provide the latched state signals 610 to the communication bus 704. In this example, the latch circuit 702-1 provides the state signal 610-1 to the communication bus 704, the latch circuit 702-2 provides the state signal 610-2 to the communication bus 704, the latch circuit 702-(N-1) provides the state signal 610-(N-1) to the communication bus 704, and the latch circuit 702-N provides the state signal 610-N to the communication bus 704. The communication bus 704 passes the state signals 610, in parallel, to the selection circuit 706. A parallel combination of the state signals 610 is represented by a composite state signal 716.

In this example, the selection-pointer generator 708 receives the counter 614 as the spare-row identifier 612. The address mapper 710 determines the address 616 of the target spare row 608 that is represented by the counter 614. In other words, the address mapper 710 decodes the counter 614 or maps (e.g., converts using a table, formula, or algorithm) the counter 614 to the address 616. The pointer generator 712 generates a pointer 714 based on the address 616. The pointer 714 enables the selection circuit 706 to identify information within the composite state signal 716 that corresponds with the target spare row 608 associated with the address 616.

The selection circuit 706 generates the selected state signal 618 based on the composite state signal 716 (e.g., the multiple state signals 610) and the pointer 714. In particular, the selection circuit 706 passes one of the state signals 610, which is identified via the pointer 714, as the selected state signal 618.

Consider an example in which the target spare row 608 represents the spare row 122-1 of FIG. 4. In this case, the pointer 714 causes the selection circuit 706 to extract the information associated with the state signal 610-1 from the composite state signal 716. The selection circuit 706 then generates the selected state signal 618 to include this extracted information. In an example implementation, the pointer 714 causes the selection circuit 706 to pass the state signal 610-1 as the selected state signal 618. The refresh logic 120 uses the selected state signal 618 to determine that the target spare row 608 (e.g., the spare row 122-1) is in the active state 406. Based on this determination, the refresh logic 120 refreshes the spare row 122-1.

Consider another example in which the target spare row 608 represents the spare row 122-N of FIG. 4. In this case, the pointer 714 causes the selection circuit 706 to extract the information associated with the state signal 610-N from the composite state signal 716. The selection circuit 706 then generates the selected state signal 618 to include this extracted information. In an example implementation, the pointer 714 causes the selection circuit 706 to pass the state signal 610-N as the selected state signal 618. The refresh logic 120 uses the selected state signal 618 to determine that the target spare row 608 (e.g., the spare row 122-N) is in the inactive state 408. Based on this determination, the refresh logic 120 skips the refresh operation (e.g., does not perform the refresh operation) on the spare row 122-N. A similar process occurs if the target spare row 608 represents the spare row 122-2 of FIG. 4, which is in the disabled state 410.

FIG. 8 illustrates a second example implementation of the spare-row state-identifier circuit 312 for performing aspects of efficient refreshing of spare rows 122. The spare-row state-identifier circuit 312 of FIG. 8 differs from the spare-row state-identifier circuit 312 of FIG. 7 by including an enable-signal generator 802 of FIG. 8 instead of the selection pointer generator 708 of FIG. 7. The spare-row state-identifier circuit 312 of FIG. 8 also differs from the spare-row state-identifier circuit 312 of FIG. 7 by being implemented without the selection circuit 706 of FIG. 7. In the depicted configuration, the enable-signal generator 802 includes at least one latch-enable circuit 804 and optionally includes the address mapper 710. The latch-enable circuit 804 is coupled to the latch circuits 702.

During operation, enable-signal generator 802 receives the counter 614 as the spare-row identifier 612. The address mapper 710 determines the address 616 of the target spare row 608 that is represented by the counter 614 (similar to the address mapper 710 of FIG. 7). The latch-enable circuit 804 generates enable signals 806-1 to 806-N. Each enable signal 806 can selectively enable or disable a corresponding latch circuit 702. An enabled latch circuit 702 can pass the corresponding state signal 610 to an output of the spare-row state-identifier circuit 312 via a wire (e.g., a communication signal path). A disabled latch circuit 702, however, does not pass the corresponding state signal 610 to the output of the spare-row state-identifier circuit 312 via the wire. The latch-enable circuit 804 selectively enables one of the latch circuits 702 that corresponds to the target spare row 608. In this way, one state signal 610 is passed to the output of the spare-row state-identifier circuit 312 at a given time. The state signal 610 that is passed by the enabled latch circuit 702 represents the selected state signal 618.

Consider an example in which the target spare row 608 represents the spare row 122-1 of FIG. 4. In this case, the latch-enable circuit 804 generates the enable signal 806-1 to enable the latch circuit 702-1 and generates the remaining enable signals 806 to disable the remaining latch circuits 702 (e.g., latch circuits 702-2 to 702-N). The enabled latch circuit 702-1 generates or passes the state signal 610-1 to the output of the spare-row state-identifier circuit 312. The spare-row state-identifier circuit 312 passes (or outputs) the state signal 610-1 as the selected state signal 618. The refresh logic 120 uses the selected state signal 618 to determine that the target spare row 608 (e.g., the spare row 122-1) is in the active state 406. Based on this determination, the refresh logic 120 refreshes the spare row 122-1.

Consider another example in which the target spare row 608 represents the spare row 122-N of FIG. 4. In this case, the latch-enable circuit 804 generates the enable signal 806-N to enable the latch circuit 702-N and generates the remaining enable signals 806 to disable the remaining latch circuits 702 (e.g., latch circuits 701-1 to 702-(N-1)). The enabled latch circuit 702-N generates or passes the state signal 610-N to the output of the spare-row state-identifier circuit 312. The remaining disabled latch circuits 702 are prevented from generating or passing the corresponding state signals 610. The spare-row state-identifier circuit 312 passes (or outputs) the state signal 610-N as the selected state signal 618. The refresh logic 120 uses the selected state signal 618 to determine that the target spare row 608 (e.g., the spare row 122-N) is in the inactive state 408. Based on this determination, the refresh logic 120 skips the refresh operation (e.g., does not perform the refresh operation) on the spare row 122-N. A similar process occurs if the target spare row 608 represents the spare row 122-2 of FIG. 4, which is in the disabled state 410.

Although not explicitly shown, the latch circuits 702 in FIGS. 7 and 8 can also be used for determining whether an address associated with a memory operation (e.g., a read operation or a write operation) has been repaired. This enables the memory device 108 to instead access the spare row 122 that effectively replaces the faulty normal row 310 within the memory array 204.

### Example Method

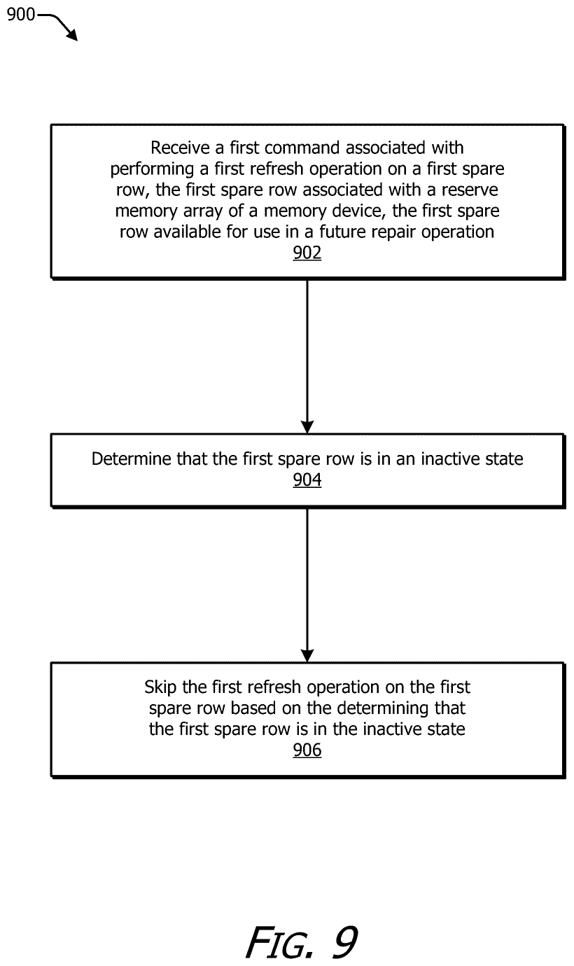

This section describes example methods for efficient refreshing of spare rows with reference to the flow diagram of FIG. 9. These descriptions may also refer to components, entities, and other aspects depicted in FIGS. 1 to 8 by way of example only. The described methods are not necessarily limited to performance by one entity or multiple entities operating on one device.

FIG. 9 illustrates a flow diagram 900, which includes operations 902 to 906. In aspects, operations of the method of the flow diagram 900 are implemented, at least in part, by the refresh logic 120 as described with reference to FIGS. 1 and 5. At 902, a first refresh command associated with performing a first refresh operation on a first spare row is received. The first spare row is associated with a reserve memory array of a memory device. The first spare row is available for use in a future repair operation. For example, the refresh logic 120 receives a first command to perform a first refresh operation on a first spare row 122, as described at 502 in FIG. 5. In this case, the first spare row 122 represents the target spare row 608. The first spare row 122 is associated with the reserve memory array 118 of the memory device 108, as shown in FIG. 4. The first spare row 122 is available for use in a future repair operation. This means that the first spare row 122 is in an inactive state 408. More specifically, the first spare row 122 is in the unused state 412, which represents a type of inactive state 408. In the example shown in FIG. 4, the first spare row 122 can represent the spare row 122-N.

At 904, the first spare row is determined to be in an inactive state. For example, the refresh logic 120 determines that the first spare row 122 is in the inactive state 408. More specifically, the refresh logic 120 can determine that the first spare row 122 is in the inactive state 408 based on the selected state signal 618 generated by the spare-row state-identifier circuit 312, as described with respect to FIG. 6. The spare-row state-identifier circuit 312 can generate the selected state signal 618 in a variety of different ways, examples of which are shown in FIGS. 7 and 8.

At 906, the first refresh operation on the first spare row is skipped based on the determining that the first spare row is in the inactive state. For example, the refresh logic 120 skips the first refresh operation on the first spare row 122 (e.g., does not perform the refresh operation on the first spare row 122) based on the determining that the first spare row 122 is in the inactive state 408. By skipping the refresh operation, the memory device 108 can conserve power and/or timing resources. The memory device 108 can optionally perform another operation responsive to the skipping of the refresh operation. For example, the memory device 108 can use the conserved resources to perform an error-correction-code operation on a normal row 310, refresh a normal row 310 to mitigate usage-based disturbance within the memory device 108, and/or refresh a different spare row 122 that is in the active state 406.

A similar method can be performed for a different spare row 122 that is disabled (e.g., spare row 122-2 of FIG. 4). In this case, the command at 902 is associated with performing a refresh operation on a spare row 122 that is not a candidate for use in a future repair operation. Steps 904 and 906 can be similar to those described above as the disabled state 410 is an example inactive state 408.

For the figures described above, the orders in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of these methods may be implemented in, for example, hardware (e.g., fixed-logic circuitry or a processor in conjunction with a memory), firmware, software, or some combination thereof. The methods may be realized using one or more of the apparatuses or components shown in FIGS. 1-7, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of effective refreshing of spare rows are described:
Example 1: A method performed by a memory device, the method comprising:
   receiving a first command associated with performing a first refresh operation on a first spare row, the first spare row associated with a reserve memory array of the memory device, the first spare row available for use in a future repair operation;
   determining that the first spare row is in an inactive state based on the first spare row being available for use in the future repair operation; and
   skipping the first refresh operation on the first spare row based on the determining that the first spare row is in the inactive state.
Example 2: The method of example 1 or any other example, further comprising:
   receiving a second command associated with performing a second refresh operation on a second spare row associated with the reserve memory array;
   determining that the second spare row is in an active state; and
   performing the second refresh operation on the second spare row based on the determining that the second spare row is in the active state.
Example 3: The method of example 2 or any other example, further comprising:
   performing a repair operation using the first spare row, the performing of the repair operation occurring after the skipping of the first refresh operation;
   receiving a third command associated with performing a third refresh operation on the first spare row;
   determining that the first spare row is in the active state based on the receiving of the third command and after the performing of the repair operation; and
   performing the third refresh operation on the first spare row based on the determining that the first spare row is in the active state.
Example 4: The method of example 3 or any other example, wherein:
   the inactive state indicates that the first spare row is not being used to repair a memory array of the memory device; and
   the active state indicates that the first spare row is used to repair a portion of the memory array.
Example 5: The method of example 1 or any other example, wherein:
   the determining that the first spare row is in the inactive state comprises:
      receiving multiple state signals from a memory storage unit of the memory device, the multiple state signals indicating respective states of multiple spare rows associated with the reserve memory array; and
      generating a selected state signal based on a spare-row identifier and the multiple state signals, the spare-row identifier representing the first spare row, the selected state signal representing a first state signal of the multiple state signals, the first state signal corresponding to the first spare row, the first state signal indicating that the first spare row is in the inactive state; and
   the skipping of the first refresh operation comprises causing the memory device to skip the first refresh operation based on the selected state signal.
Example 6: The method of example 5 or any other example, further comprising:
   respectively storing the multiple state signals provided by the memory storage unit using multiple latch circuits, the multiple latch circuits respectively associated with the multiple spare rows within the reserve memory array;
   generating a pointer based on the spare-row identifier;
   passing the multiple state signals in parallel across a communication bus from the multiple latch circuits to a selection circuit;
   selecting, by the selection circuit, the first state signal from the multiple state signals based on the pointer; and
   generating, by the selection circuit, the selected state signal to comprise information carried by the first state signal.
Example 7: The method of example 5 or any other example, further comprising:
   respectively storing the multiple state signals provided by the memory storage unit using multiple latch circuits, the multiple latch circuits respectively associated with the multiple spare rows within the reserve memory array;
   enabling, based on the spare-row identifier, a first latch circuit of the multiple latch circuits to pass the corresponding first state signal as the selected state signal; and
   disabling, based on the spare-row identifier, remaining ones of the multiple latch circuits to prevent passing remaining ones of the multiple state signals as the selected state signal.
Example 8: The method of example 5 or any other example, wherein the spare-row identifier comprises:
   a counter having a value associated with the first spare row; or
   an address associated with the first spare row.
Example 9: The method of example 1 or any other example, further comprising, responsive to the skipping of the first refresh operation:
   performing an error-correction-code operation on a first normal row associated with a memory array of the memory device;
   refreshing a second normal row associated with the memory array to mitigate usage-based disturbance within the memory device; or
   refreshing a second spare row of the reserve memory array based on a determination that the second spare row is in an active state.
Example 10: An apparatus comprising:
   a memory device comprising:
      a reserve memory array comprising a first spare row, the first spare row available for use in a future repair operation; and
      refresh logic configured to:
         receive a first command associated with performing a first refresh operation on the first spare row;
         determine that the first spare row is in an inactive state based on the first spare row being available for use in the future repair operation; and
         skip the first refresh operation on the first spare row based on the determination that the first spare row is in the inactive state.
Example 11: The apparatus of example 10 or any other example, wherein:
   the memory device is configured to perform a repair operation using the first spare row, the repair operation occurring after the refresh logic skipped the first refresh operation; and
   the refresh logic is configured to:
      receive a second command associated with performing a second refresh operation on the first spare row;
      determine that the first spare row is in an active state based on the received second command and after the repair operation is performed; and
      perform the second refresh operation on the first spare row based on the determination that the first spare row is in the active state.
Example 12: The apparatus of example 10 or any other example, wherein the memory device is configured to, responsive to skipping the first refresh operation:
   perform an error-correction-code operation on a first normal row associated with a memory array of the memory device;
   refresh a second normal row associated with the memory array to mitigate usage-based disturbance within the memory device; or
   refresh a second spare row of the reserve memory array based on a determination that the second spare row is in an active state.
Example 13: The apparatus of example 10 or any other example, further comprising:
   a memory storage unit; and
   a spare-row state-identifier circuit comprising:
      multiple latch circuits coupled to the memory storage unit and configured to respectively store multiple state signals provided by the memory storage unit, the multiple latch circuits respectively associated with multiple spare rows within the reserve memory array;
      a selection-pointer generator configured to generate a pointer based on a spare-row identifier;
      a communication bus that is coupled to the multiple latch circuits; and
      a selection circuit coupled to the selection-pointer generator, the communication bus, and the refresh logic, the selection circuit configured to:
         receive, in parallel and via the communication bus, the multiple state signals stored by the multiple latch circuits; and
         pass, to the refresh logic and based on the pointer, a first state signal of the multiple state signals as a selected state signal,
   wherein the refresh logic is configured to determine that the first spare row is in the inactive state based on the selected state signal.
Example 14: The apparatus of example 10 or any other example, further comprising:
   a memory storage unit; and
   a spare-row state-identifier circuit comprising:
      multiple latch circuits coupled to the memory storage unit and configured to respectively store multiple state signals provided by the memory storage unit, the multiple latch circuits respectively associated with multiple spare rows within the reserve memory array; and
      an enable-signal generator configured to:
         enable, based on a spare-row identifier, a first latch circuit of the multiple latch circuits to pass a corresponding first state signal of the multiple state signals as the selected state signal; and
         disable, based on the spare-row identifier, remaining ones of the multiple latch circuits to prevent passing remaining ones of the multiple state signals as the selected state signal;
   wherein the refresh logic is configured to determine that the first spare row is in the inactive state based on the selected state signal.
Example 15: A memory device comprising:
   a reserve memory array comprising multiple spare rows, a first set of the multiple spare rows being in an active state, a second set of the multiple spare rows being in an inactive state, at least one spare row of the second set being available for use in a future repair operation; and
   refresh logic configured to:
      refresh the first set of the multiple spare rows that are in the active state; and
      skip refreshing of the second set of the multiple spare rows that are in the inactive state.
Example 16: The memory device of example 15 or any other example, wherein:
   the active state indicates that spare rows within the first set of the multiple spare rows are being used to repair a portion of a memory array of the memory device; and
   the inactive state indicates that other spare rows within the second set of the multiple spare rows are not being used to repair the memory array.
Example 17: The memory device of example 15 or any other example, wherein at least one other spare row of the second set is not available for use in the future repair operation.
Example 18: The memory device of example 15 or any other example, further comprising:
   a memory storage unit configured to generate multiple state signals indicating respective states of the multiple spare rows; and
   a spare-row state-identifier circuit coupled to the memory storage unit and the refresh logic, the spare-row state-identifier circuit configured to:
      receive the multiple state signals from the memory storage unit;
      receive spare-row identifiers from the refresh logic, each spare-row identifier of the spare-row identifiers identifying one of the multiple spare rows; and
      generate selected state signals based on the spare-row identifiers and the multiple state signals, each one of the selected state signals comprising one of the multiple state signals corresponding to the spare-row identifier,
   wherein the refresh logic is configured to refresh the first set of the multiple spare rows and skip refreshing of the second set of the multiple spare rows based on the selected state signals provided by the spare-row state-identifier circuit.
Example 19: The memory device of example 18 or any other example, wherein the spare-row state-identifier circuit comprises:
   multiple latch circuits configured to store the multiple state signals provided by the memory storage unit;
   a communication bus that is coupled to the multiple latch circuits; and
   a selection circuit that is coupled to the communication bus, the selection circuit configured to:
      receive, in parallel and via the communication bus, the multiple state signals stored by the multiple latch circuits; and
      pass, as a selected state signal, one of the multiple state signals that corresponds to a spare-row identifier of the spare-row identifiers, the spare-row identifier and the one of the multiple state signals being associated with a same spare row of the multiple spare rows.
Example 20: The memory device of example 18 or any other example, wherein the spare-row state-identifier circuit comprises:
   multiple latch circuits configured to store the multiple state signals provided by the memory storage unit;
   a communication bus that is coupled to the multiple latch circuits, the communication bus configured to pass a selected state signal to the refresh logic; and
   an enable-signal generator that is coupled to the multiple latch circuits, the enable-signal generator configured to:
      generate multiple enable signals corresponding to the multiple latch circuits; and
      cause, based on the multiple enable signals, one of the multiple latch circuits to pass a corresponding state signal of the multiple state signals to the communication bus.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### Conclusion

Although aspects of performing efficient refreshing of spare rows have been described in language specific to certain features and/or methods, the subject of the appended claims is not necessarily limited to the specific features or methods described. Rather, the specific features and methods are disclosed as a variety of example implementations of the efficient refreshing of spare rows.

What is claimed is:

1. A method performed by a memory device, the method comprising:
receiving a first command associated with performing a first refresh operation on a first spare row, the first spare row associated with a reserve memory array of the memory device, the first spare row available for use in a future repair operation;
determining that the first spare row is in an inactive state based on the first spare row being available for use in the future repair operation; and
skipping the first refresh operation on the first spare row based on the determining that the first spare row is in the inactive state.

2. The method of claim 1, further comprising:
receiving a second command associated with performing a second refresh operation on a second spare row associated with the reserve memory array;
determining that the second spare row is in an active state; and
performing the second refresh operation on the second spare row based on the determining that the second spare row is in the active state.

3. The method of claim 2, further comprising:
performing a repair operation using the first spare row, the performing of the repair operation occurring after the skipping of the first refresh operation;
receiving a third command associated with performing a third refresh operation on the first spare row;
determining that the first spare row is in the active state based on the receiving of the third command and after the performing of the repair operation; and
performing the third refresh operation on the first spare row based on the determining that the first spare row is in the active state.

4. The method of claim 3, wherein:
the inactive state indicates that the first spare row is not being used to repair a memory array of the memory device; and
the active state indicates that the first spare row is used to repair a portion of the memory array.

5. The method of claim 1, wherein:
the determining that the first spare row is in the inactive state comprises:
receiving multiple state signals from a memory storage unit of the memory device, the multiple state signals indicating respective states of multiple spare rows associated with the reserve memory array; and
generating a selected state signal based on a spare-row identifier and the multiple state signals, the spare-row identifier representing the first spare row, the selected state signal representing a first state signal of the multiple state signals, the first state signal corresponding to the first spare row, the first state signal indicating that the first spare row is in the inactive state; and
the skipping of the first refresh operation comprises causing the memory device to skip the first refresh operation based on the selected state signal.

6. The method of claim 5, further comprising:
respectively storing the multiple state signals provided by the memory storage unit using multiple latch circuits, the multiple latch circuits respectively associated with the multiple spare rows within the reserve memory array;
generating a pointer based on the spare-row identifier;
passing the multiple state signals in parallel across a communication bus from the multiple latch circuits to a selection circuit;
selecting, by the selection circuit, the first state signal from the multiple state signals based on the pointer; and
generating, by the selection circuit, the selected state signal to comprise information carried by the first state signal.

7. The method of claim 5, further comprising:
respectively storing the multiple state signals provided by the memory storage unit using multiple latch circuits, the multiple latch circuits respectively associated with the multiple spare rows within the reserve memory array;
enabling, based on the spare-row identifier, a first latch circuit of the multiple latch circuits to pass the corresponding first state signal as the selected state signal; and
disabling, based on the spare-row identifier, remaining ones of the multiple latch circuits to prevent passing remaining ones of the multiple state signals as the selected state signal.

8. The method of claim 5, wherein the spare-row identifier comprises:
a counter having a value associated with the first spare row; or an address associated with the first spare row.

9. The method of claim 1, further comprising, responsive to the skipping of the first refresh operation:
performing an error-correction-code operation on a first normal row associated with a memory array of the memory device;
refreshing a second normal row associated with the memory array to mitigate usage-based disturbance within the memory device; or
refreshing a second spare row of the reserve memory array based on a determination that the second spare row is in an active state.

10. An apparatus comprising:
a memory device comprising:
a reserve memory array comprising a first spare row, the first spare row available for use in a future repair operation; and
refresh logic configured to:
receive a first command associated with performing a first refresh operation on the first spare row;
determine that the first spare row is in an inactive state based on the first spare row being available for use in the future repair operation; and
skip the first refresh operation on the first spare row based on the determination that the first spare row is in the inactive state.

11. The apparatus of claim 10, wherein:
the memory device is configured to perform a repair operation using the first spare row, the repair operation occurring after the refresh logic skipped the first refresh operation; and
the refresh logic is configured to:
receive a second command associated with performing a second refresh operation on the first spare row;
determine that the first spare row is in an active state based on the received second command and after the repair operation is performed; and
perform the second refresh operation on the first spare row based on the determination that the first spare row is in the active state.

12. The apparatus of claim 10, wherein the memory device is configured to, responsive to skipping the first refresh operation:
perform an error-correction-code operation on a first normal row associated with a memory array of the memory device;
refresh a second normal row associated with the memory array to mitigate usage-based disturbance within the memory device; or
refresh a second spare row of the reserve memory array based on a determination that the second spare row is in an active state.

13. The apparatus of claim 10, further comprising:
a memory storage unit; and
a spare-row state-identifier circuit comprising:
multiple latch circuits coupled to the memory storage unit and configured to respectively store multiple state signals provided by the memory storage unit, the multiple latch circuits respectively associated with multiple spare rows within the reserve memory array;
a selection-pointer generator configured to generate a pointer based on a spare-row identifier;
a communication bus that is coupled to the multiple latch circuits; and
a selection circuit coupled to the selection-pointer generator, the communication bus, and the refresh logic, the selection circuit configured to:
receive, in parallel and via the communication bus, the multiple state signals stored by the multiple latch circuits; and
pass, to the refresh logic and based on the pointer, a first state signal of the multiple state signals as a selected state signal,
wherein the refresh logic is configured to determine that the first spare row is in the inactive state based on the selected state signal.

14. The apparatus of claim 10, further comprising:
a memory storage unit; and
a spare-row state-identifier circuit comprising:
multiple latch circuits coupled to the memory storage unit and configured to respectively store multiple state signals provided by the memory storage unit, the multiple latch circuits respectively associated with multiple spare rows within the reserve memory array; and
an enable-signal generator configured to:
enable, based on a spare-row identifier, a first latch circuit of the multiple latch circuits to pass a corresponding first state signal as a selected state signal; and
disable, based on the spare-row identifier, remaining ones of the multiple latch circuits to prevent passing remaining ones of the multiple state signals to the as the selected state signal;
wherein the refresh logic is configured to determine that the first spare row is in the inactive state based on the selected state signal.

15. A memory device comprising:
a reserve memory array comprising multiple spare rows, a first set of the multiple spare rows being in an active state, a second set of the multiple spare rows being in an inactive state, at least one spare row of the second set being available for use in a future repair operation; and
refresh logic configured to:
refresh the first set of the multiple spare rows that are in the active state; and
skip refreshing of the second set of the multiple spare rows that are in the inactive state.

16. The memory device of claim 15, wherein:
the active state indicates that spare rows within the first set of the multiple spare rows are being used to repair a portion of a memory array of the memory device; and
the inactive state indicates that other spare rows within the second set of the multiple spare rows are not being used to repair the memory array.

17. The memory device of claim 15, wherein at least one other spare row of the second set is not available for use in the future repair operation.

18. The memory device of claim 15, further comprising:
a memory storage unit configured to generate multiple state signals indicating respective states of the multiple spare rows; and
a spare-row state-identifier circuit coupled to the memory storage unit and the refresh logic, the spare-row state-identifier circuit configured to:
receive the multiple state signals from the memory storage unit;
receive spare-row identifiers from the refresh logic, each spare-row identifier of the spare-row identifiers identifying one of the multiple spare rows; and
generate selected state signals based on the spare-row identifiers and the multiple state signals, each one of the selected state signals comprising one of the multiple state signals corresponding to the spare-row identifier,
wherein the refresh logic is configured to refresh the first set of the multiple spare rows and skip refreshing of the second set of the multiple spare rows based on the selected state signals provided by the spare-row state-identifier circuit.

19. The memory device of claim 18, wherein the spare-row state-identifier circuit comprises:
multiple latch circuits configured to store the multiple state signals provided by the memory storage unit;
a communication bus that is coupled to the multiple latch circuits; and
a selection circuit that is coupled to the communication bus, the selection circuit configured to:
receive, in parallel and via the communication bus, the multiple state signals stored by the multiple latch circuits; and
pass, as a selected state signal, one of the multiple state signals that corresponds to a spare-row identifier of the spare-row identifiers, the spare-row identifier and the one of the multiple state signals being associated with a same spare row of the multiple spare rows.

20. The memory device of claim 18, wherein the spare-row state-identifier circuit comprises:
multiple latch circuits configured to store the multiple state signals provided by the memory storage unit;
a wire that is coupled to the multiple latch circuits, the wire configured to pass a selected state signal to the refresh logic; and
an enable-signal generator that is coupled to the multiple latch circuits, the enable-signal generator configured to:
generate multiple enable signals corresponding to the multiple latch circuits; and
cause, based on the multiple enable signals, one of the multiple latch circuits to pass a corresponding state signal of the multiple state signals to the wire.
